(19) United States
(12) Patent Application Publication
(10) Pub. No.: US 2007/0262305 A1
(43) Pub. Date: Nov. 15, 2007

(54) INTEGRATED CIRCUIT PROTECTION FROM ESD DAMAGE DURING FABRICATION

(76) Inventors: James W. Adkisson, Jericho, VT (US); Jeffrey P. Gambino, Westford, VT (US); Richard J. Rassel, Colchester, VT (US); Steven H. Voldman, South Burlington, VT (US)

Correspondence Address: EDWARD W. BROWN, 46 PHEASANT RUN, WILTON, CT, 06897, US

(21) Appl. No.: 11/382,492

(22) Filed: May 10, 2006

(51) Int. Cl. H01L 23/58

(52) U.S. Cl. 257/48

(57) ABSTRACT

A semiconductor integrated circuit wafer containing a plurality of integrated circuit chips and having a common substrate, each chip formed with an internal region in the interior of the chip and a removable external region on the perimeter of the internal region and circuitry disposed preferably in the external region and connected to at least one pad of an integrated circuit chip and the wafer substrate to establish electrical connection during electrostatic discharge and prevent ESD damage. The pad and substrate are isolated during tested of the integrated circuit chips in the wafer. Preferably, the external region is removed when the integrated circuit chips are diced from the wafer.

### FIELD OF INVENTION

This invention relates generally to microelectronic or integrated circuit chips and, more particularly, to integrated circuit chips having a structure to prevent damage from electrostatic discharge (ESD).

### BACKGROUND OF THE INVENTION

ESD damage can occur during manufacture and of the integrated circuit wafer containing integrated circuit chips when a wafer is exposed to static electricity by sliding across another ungrounded surface or touched by an ungrounded person handling the wafer. The damage, such as dielectric failure, will result between the signal lines and pad wires, crack stops, guard rings and internal circuitry of the integrated circuit. Protection from such damage during manufacture is needed without impacting manufacturing, testing, yield or performance of the integrated circuit.

### SUMMARY OF THE INVENTION

Therefore, it is a primary object of the present invention to provide an improved structure in the wafer for the integrated circuit chips to prevent ESD during manufacture of a wafer containing the integrated circuit chips.

Another object of the present invention to provide the improved structure in the wafer without impacting manufacture, testing, yield or performance of the integrated circuits in the wafer.

A further object of the present invention is to provide an improved structure in the wafer which protects the integrated circuit chip during manufacturing and yet allows a test function to be performed.

The foregoing and other objects are achieved by forming integrated circuit chips on the wafer each comprising, preferably, an integrated circuit region and an ESD damage protective circuitry region in the wafer which electrically shorts all of the integrated circuit pads to substrate ground of the wafer and includes a test function circuit in series between the pads and the substrate. The test function circuit normally is unbiased and the ESD damage protective circuitry allows electrical connectivity between the pads and the wafer substrate. When a test is to be performed, the pads and the substrate ground are electrically separated by a test function enable and a test can be performed on the integrated circuits in the wafer.

### BRIEF DESCRIPTION OF THE DRAWINGS

The foregoing and other objects, aspects and advantages will be better understood from the following detailed description of preferred embodiments of the invention with reference in the drawings, in which:

FIG. 1 (PRIOR ART) is a cross-sectional view showing a portion of an integrated circuit chip containing field effect transistors (FET)s and identifying where ESD damage occurs and where the dicing line for cutting the chip out of the wafer.

FIG. 2 (PRIOR ART) is a plan view showing a pair of adjacent integrated circuit chips with pads for connecting interior circuits to a package substrate (not shown) and dicing lines for cutting the chip out of the wafer.

FIG. 3 is a cross-sectional view of the similar portion of an integrated circuit chip as FIG. 1 of the integrated circuit chip of a wafer containing a field effect transistor (FET) but, in addition, identifying a block of circuitry of the present invention outside of the dicing line and in an external region larger than the region or kerf area of FIG. 1.

FIG. 4 is a plan view of a similar pair of adjacent integrated circuit chips as FIG. 2 but, in addition, identifying a block of circuitry of the present invention outside the dicing lines of the adjacent chips and in an external region larger than the region or kerf area of FIG. 2.

FIG. 5 is a circuit diagram of the preferred circuitry block of the present invention and shows a soft grounded gated NMOS connected to an integrated circuit pad.

FIG. 6 is an enlarged plan view of another embodiment of the present invention, relative to FIG. 5, showing a MOSFET with a source/drain salicide block.

FIG. 7 is a circuit diagram of another embodiment of the present invention showing double diode connected to an integrated circuit pad.

FIG. 8 is a circuit diagram of another embodiment of the present invention showing a rail-to-rail diode string.

### DETAILED DESCRIPTION OF THE PREFERRED EMBODIMENTS OF THE INVENTION

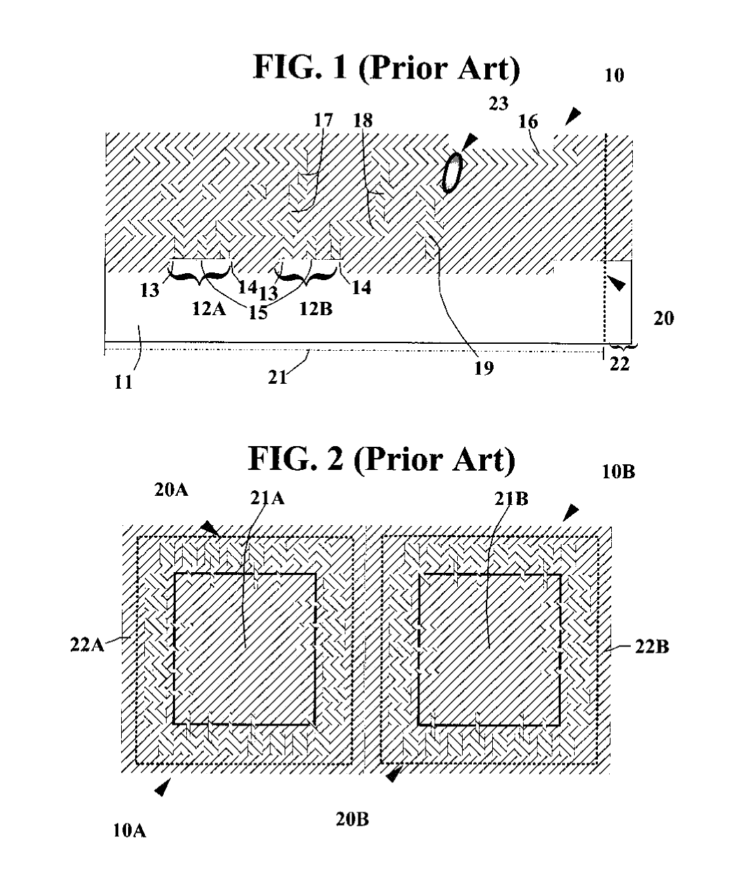

To be able to better understand the present invention and the preferred embodiment encompassing the invention, the Prior Art as shown in FIGS. 1-2 will first be described. FIG. 1 (Prior Art) shows a portion of an integrated circuit 10 in a semiconductor wafer comprising a substrate 11 with field effect transistors (FET)s 12A and 12B, each with a source 13, drain 14 and gate 15. The source, drain and gates are connected within the integrated circuit and to pads 16 at the top or surface of the integrated circuit by vias 17 and interconnects 18. Surrounding the periphery of the integrated circuit is a crack stop 19 to prevent cracks in the integrated circuit chips during dicing of the wafer. The dicing line is identified by the arrow 20. The integrated circuit components 12A and 12B and interconnect 18, the crack stop 19 and the pads 16 are within the internal region 21 of the chip in the wafer, and the area outside the dicing line 20 is the external region 22 of the chip in the wafer. During manufacturing of the wafer, electrostatic discharge (ESD) occurs and damage results between the crack stop 19 and the pad 16, as indicated by the arrow 23.

FIG. 2 (Prior Art) is a plan view or the top of a pair of integrated circuit chips 10A and 10B in a wafer in which each of the internal regions 21A and 21B contains pads 16, interconnects 18 and crack stop 19 and is within each of the dicing lines 20A and 20B, respectively. Each of the external regions 22A and 22B is outside the dicing lines 20A and 20B, respectively, and is relatively narrow since it is the kerf area and will be discarded after the wafer is diced into individual integrated circuit chips.

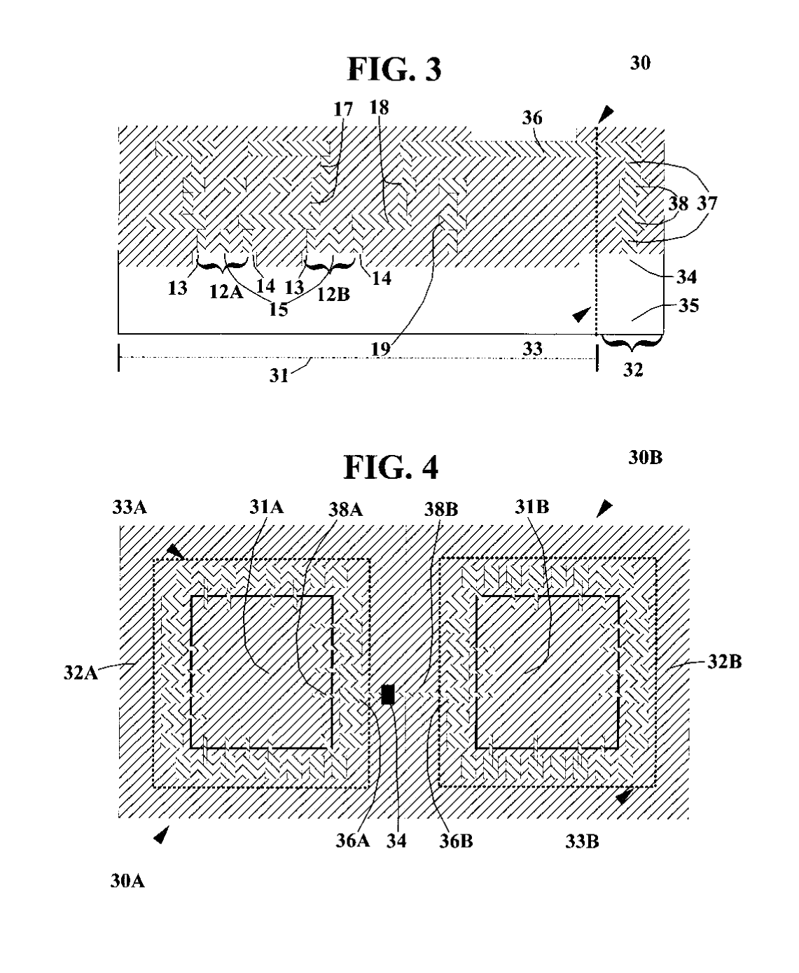

Now, in accordance with the preferred embodiment of the present invention, FIG. 3 shows a similar portion of an integrated circuit chip 30 in a wafer in a cross-sectional view as FIG. 1 (Prior Art), in that it comprises FETs 12A and 12B each with a source 13, drain 14 and gate 15. It also comprises vias 17 and interconnectsl8 and a crack stop 19. Although the internal region 31 inside the dicing line 33 is the same size as the internal region of FIG. 1 (Prior Art), the external region 32 or kerf is outside of the dicing line 33 is substantially wider and is sufficient in size to preferably contain circuitry 34 to prevent the ESD damage as shown in FIG. 1 (Prior Art). The ESD damage protection circuitry 34 is shown generally in the wafer substrate 35 and is connected to the pad 36 through vias 37 and interconnects 38 and protects the integrated circuit chip during manufacturing of the integrated circuits but permits testing of the integrated circuit. After testing, the wafer is diced along the dicing line 33 into an individual integrated circuit chip and external region 32 or kerf herein is discarded along with the circuitry 34.

FIG. 4 is a plan view or the top of a pair of adjacent integrated circuit chips 30A and 30B which are similar to FIG. 2 (Prior Art), but each integrated circuit chip 30A and 30B preferably are fabricated with an external region 32A and 32B of sufficient width to contain circuitry 34 to prevent ESD damage during manufacturing and testing The ESD damage protection circuitry 34 is indicated as a block 34 in the external region 32A of integrated circuit chip 30A and is connected to pads 36A and 36B on chips 30A and 30B by interconnects 38A and 38B. It should be appreciated that the block of circuitry 34 can be fabricated in the external region 32 of each of the integrated circuit chips in the wafer or it can be shared between adjacent chips as shown in FIG. 4. In addition, the circuitry 34 can be positioned in the corner external region 32 and be shared by three and even four adjacent chips which meet at the corner of the three or four chips. The ESD damage protection circuitry in the wafer electrically shorts the integrated circuit pads to substrate ground of the wafer and includes a test function circuit in series between the pads and the substrate. The test function circuit normally is unbiased and the ESD damage protective circuitry allows electrical connectivity between the pads and the wafer substrate. When a test is to be performed, the pads and the substrate ground are electrically separated by a test function enable signal and a test can be performed on the integrated circuits in the wafer. The specific ESD damage protection circuits for the block of circuitry 34 will be described in reference to the following Figures.

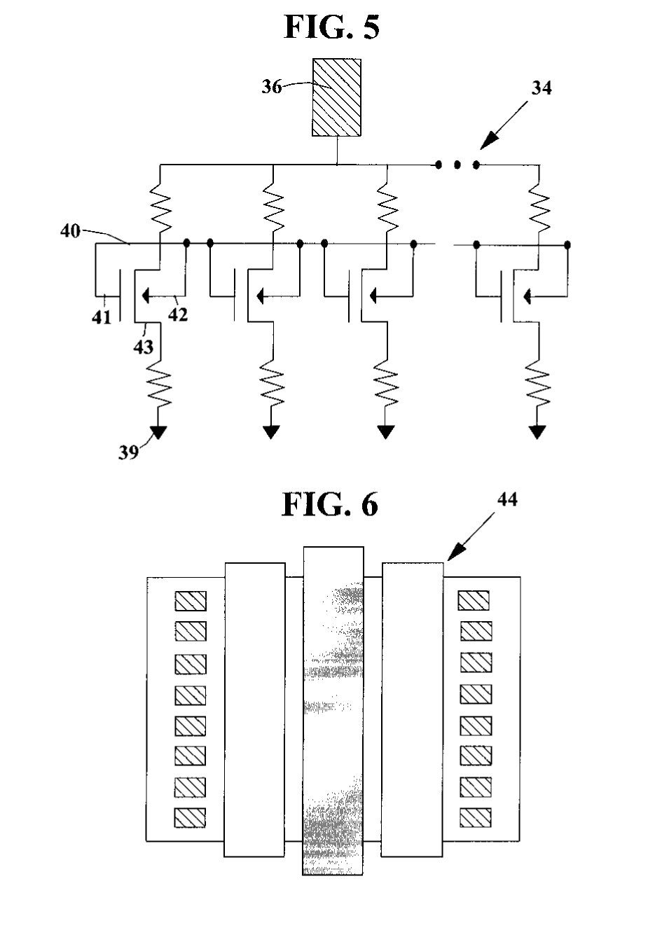

In FIG. 5, which is the preferred embodiment for the circuitry 34, the circuitry is a MOSFET 40 and is formed preferably in the external region 32 (FIG. 3 and 4) and is connected to a pad 36 and ground 39. The MOSFET 40 is shown as an infinite number of FETs, but one FET is sufficient for ESD damage protection. In operation of the circuit, as the voltage on the pad 36 increases, the MOSFET drain(s) 41 begins to avalanche. This leads to an increase in the substrate current. As the MOSFET substrate voltage increases, the forward bias of the MOSFET source(s) 42 occurs leading to MOSFET snapback. Additionally, as the substrate current increases, the threshold voltage of the MOSFET gate 43 voltage increases, when it exceeds the MOSFET threshold voltage, it turns on, leading to MOSFET transistor conduction. If an electrostatic discharge occurs, it will generate an increase in voltage and, when it exceeds the MOSFET's snapback voltage, it will cause the MOSFET to conduct, thereby electrically connecting the MOSFET to substrate ground and preventing ESD damage. During testing, the MOSFET is turned off and the pads and substrate ground are electrically separated.

To improve current distribution and MOSFET feedback, resistor elements are placed in series. As shown by the arrow 44 in FIG. 6, enlarged silicon block masks, which are well know in the art, are used in the MOSFET source 42 and drain 41 region(s). The silicide block masks prevent formation of a silicide under the mask, thereby separating the refractory metal via 37 (FIG. 4) from the silicon surface. A silicide mask creates a series and lateral resistance in the MOSFET source 42 and drain 41 region(s). As the voltage on the pad 36 increases, the MOSFET drain(s) begins to avalanche. This leads to an increase in the substrate current. As the MOSFET substrate voltage increases, the forward bias of the MOSFET source(s) 42 occurs, leading to MOSFET snapback. In high current mode of operation, current constriction is avoided due to the thermal and electrical feedback induced by the source resistor elements. Again, if electrostatic discharge occurs and exceeds the snapback voltage, the MOSFET is connected to ground and damage is prevented.

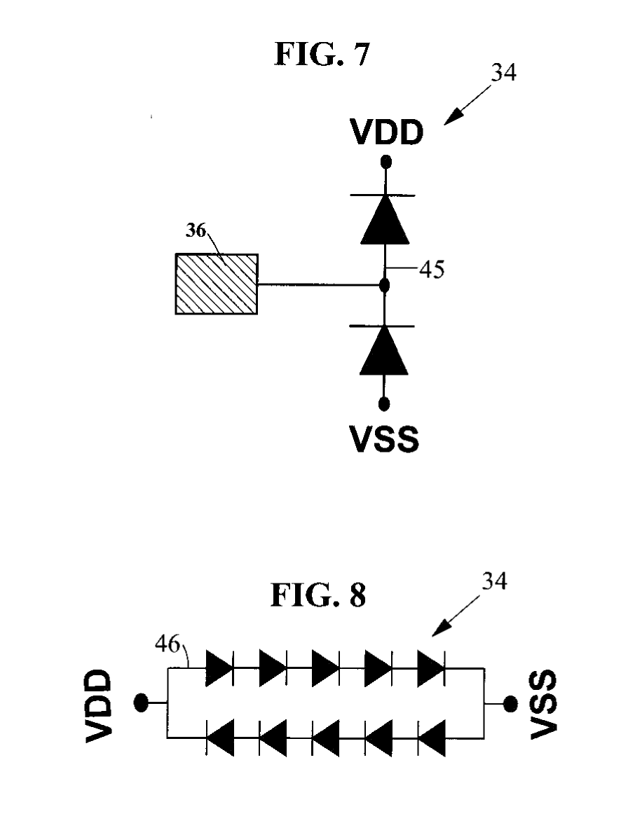

An alternate embodiment of an ESD damage protection circuit 34 is shown in FIG. 7, in which the circuit, herein a dual P-N diode 45, is formed between a pad 36 and both VDD and VSS rails. In operation with ESD positive polarity, a first P-N diode forward biases between the pad 36 and the VDD power rail. For a negative polarity ESD event, the second P-N diode forward biases between the pad 36 and the VSS power rail.

A further alternate embodiment of an ESD damage protection circuit 34 is shown in FIG. 8, in which the circuit, herein a rail-to-rail P-N diode string 46, is formed between any two power rails, such as VDD and VSS rails. In operation for a positive polarity from an electrostatic discharge, the P-N diode string forward biases between the VDD and VSS power rails and prevents ESD damage. For negative polarity from an electrostatic discharge, the P-N diode string forward biases between the VSS and the VDD power rails and ESD damage is prevented.

Although this invention has been described relative to specific embodiments for purposes of understanding, it will be realized that alterations and modifications may be made thereto without departing from the scope of the following claims. Therefore, the present embodiments are to be considered as illustrative and not restricted, and the invention is not to be limited to the details given herein, but may be modified within the scope and equivalents of the following claims.

What is claimed is:

1. A semiconductor integrated circuit wafer containing a plurality of integrated circuit chips and having a common substrate comprising:
a semiconductor wafer having a plurality integrated circuit chips, each chip formed with an internal region in the interior of the chip and a removable external region on the perimeter of the internal region:;
signal pads disposed on the outer periphery of the internal region;
circuitry disposed in the external region;
a first interconnect extending to or being part of at least one of the signal pads of the integrated circuit chip and connecting the circuitry; and
a second interconnect in the external region and connecting said circuitry to the wafer substrate, whereby electrical connection is established between the integrated circuit chip containing the pad and the substrate of the wafer and ESD damage will be prevented.

2. The semiconductor wafer of claim 1 wherein said circuitry is disposed in the external region of one of a pair of adjacent integrated circuit chips, each having a pad connected to the circuitry.

3. The semiconductor wafer of claim 1 wherein said circuitry is disposed in the external the region of each of integrated circuit chips in the wafer, each having a pad connected to the circuitry.

4. The semiconductor wafer of claim 1 wherein said circuitry is disposed in one of the external regions in the corner of four adjacent integrated circuit chips in the wafer, each having a pad connected to the circuitry.

5. The integrated circuit wafer of claim 1 wherein the damage preventing circuitry is a MOSFET.

6. The integrated circuit wafer of claim 5 wherein the MOSFET includes silicon block masks.

7. The integrated circuit wafer of claim 1 wherein the damage preventing circuitry is a dual P-N diode.

8. The integrated circuit wafer of claim 1 wherein the damage presenting circuitry is a rail-to-rail P-N diode string.

9. A method for fabricating semiconductor integrated circuit wafer containing a plurality of integrated circuit chips and having a common substrate comprising:
forming a plurality integrated circuit chips in a semiconductor wafer, each chip being formed with an internal region in the interior of the chip and a removable external region on the perimeter of the internal region;
forming signal pads on the outer periphery of the internal region;
forming circuitry in the external region;
forming a first interconnect extending to or being part of at least one of the signal pads of the integrated circuit chip and connecting the circuitry; and
forming a second interconnect in the external region and connecting said circuitry to the wafer substrate, whereby electrical connection is established between the integrated circuit chip containing the pad and the substrate of the wafer and ESD damage will be prevented.

10. The method claim 9 wherein said circuitry is formed in the external region of one of a pair of adjacent integrated circuit chips, each having a pad formed to connect to the circuitry.

11. The method of claim 9 wherein said circuitry is formed in the external the region of each of integrated circuit chips in the wafer, each having a pad formed to connect to the circuitry.

12. The method of claim 9 wherein said circuitry is formed in one of the external regions in the corner of four adjacent integrated circuit chips in the wafer, each having a pad formed to connect to the circuitry.

13. A semiconductor integrated circuit wafer containing a plurality of integrated circuit chips and having a common substrate comprising:
a semiconductor wafer having a plurality integrated circuit chips with a common substrate, each chip formed with an internal region in the interior of the chip and containing a crack stop adjacent the perimeter of the internal region;
signal pads disposed adjacent the crack stop;
circuitry for preventing ESD damage disposed in the integrated circuit chip; and
an interconnect extending to or being part of at least one of the signal pads of the integrated circuit chip and connecting said circuitry and the wafer substrate, whereby electrical connection is established between the integrated circuit chip containing the pad and the substrate of the wafer and ESD damage is prevented.

14. The integrated circuit wafer of claim 13 wherein the damage preventing circuitry is formed in an exterior region of an integrated circuit chip and is removable during dicing of the wafer.

15. The integrated circuit wafer of claim 13 wherein a signal pad is in the internal region of the integrated circuit chip and inside the crack stop and the damage preventing circuitry is formed in the internal region of the chip.

16. The integrated circuit wafer of claim 13 wherein, during testing of the integrated circuits, the signal pads and substrate are isolated.

17. The integrated circuit wafer of claim 13 wherein the damage preventing circuitry is a MOSFET.

18. The integrated circuit wafer of claim 17 wherein the MOSFET includes silicon block masks.

19. The integrated circuit wafer of claim 13 wherein the damage preventing circuitry is a dual P-N diode.

20. The integrated circuit wafer of claim 13 wherein the damage presenting circuitry is a rail-to-rail P-N diode string.
